(19) United States
(12) Patent Application Publication
(10) Pub. No.: US 2006/0071152 A1
(43) Pub. Date: Apr. 6, 2006

(54) Semiconductor device and method for producing same

(75) Inventor: Atsushi Ono, Yamatokoriyama-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/240,649

(22) Filed: Oct. 3, 2005

(30) Foreign Application Priority Data
Oct. 4, 2004 (JP) 2004-291261

(51) Int. Cl. H01L 31/00

(52) U.S. Cl. 250/214.1

(57) ABSTRACT

A wafer-level chip scale package in which a semiconductor element is encapsulated in a hollow structure that is not easily filled with moisture is provided. Also provided is a method for producing such a package. The semiconductor device has a semiconductor substrate; a semiconductor element provided in an element region on one principal surface of the semiconductor substrate; a sealing material provided on the one principal surface and enclosing the element region: and a light transmission material adhered to the semiconductor substrate via the sealing material. The light transmission material and the element region define a hollow between the light transmission material and the element region. In the light transmission material, through holes penetrating through the principal surfaces of the light transmission material are provided. The inner side opening of each of the through holes communicates with the hollow.

This non-provisional application claims priority under 35 U.S.C. §119(a) on Japanese Patent application No. 2004-291261 filed in Japan on Oct. 4, 2004, the entire contents of which are hereby incorporated by reference.

### BACKGROUND OF THE INVENTION

1) Field of the Invention

The present invention relates to a semiconductor device and a method for producing the same, and more particularly to a semiconductor device in which a semiconductor element is encapsulated in a package of hollow structure, and to a method for producing such a semiconductor device.

2) Description of the Related Art

Semiconductor devices equipped with light receiving sensors (semiconductor elements) such as CCD and CMOS imagers generally have the structure in which the light receiving sensor is encapsulated in a hollow portion of the package.

Specifically, FIG. 11 shows an example of the structure of the light receiving sensor encapsulated in the hollow. In the hollow of hollow container 115, semiconductor chip 101 that acts as the light receiving sensor and has imaging element 113 and micro lenses 114 is mounted via die bonding material 117, and glass lid 112 is adhered on upper portions of hollow container 115 via adhesives 119. FIG. 12 shows another example of the structure. On substrate 120, semiconductor chip 101 is mounted via die bonding material 117, and semiconductor chip 101 is encapsulated in the hollow of bell-shaped holder 122 equipped with glass lid 112 and lenses 123.

In these light-receiving semiconductor devices of the prior art, it is not easy to completely prevent water from infiltrating into the hollow at the time of device production, and thus such problems arise that moisture is filled in the hollow container causing degradation of the semiconductor chip, and that dew condensation occurs on the glass lid which hinders light receiving, resulting in mal-operation of the device. In addition, even if the infiltration of water can be prevented at the time of production, water penetration because of inserted materials such as adhesive cannot be completely prevented. Thus, when the device is used for a long period of time, by accumulation of minute amounts of water infiltration, moisture can be filled in the hollow container.

On the other hand, to extract the element output out of the device, it is necessary to provide a space in the hollow container in which, for example, wire 118 connects electrode pad 109 of semiconductor chip 101 to electrode lead 116 extended outside the package. This presents such a problem that the semiconductor device cannot be sufficiently miniaturized.

In view of this, there is such a technique that the hollow between the semiconductor chip and sealing glass is filled with a transparent adhesive, and a penetrating electrode is provided inside the substrate, thereby preventing the problems resulting from moisture and reducing the space for use in extracting the element output out of the device (see, for example, patent document 1).

Patent Document 1: Japanese Patent application Publication No. 2002-94082 (Page 2)

Although the technique described in patent document 1 alleviates the problems resulting from moisture, because the transparent adhesive used for filling the hollow causes light scattering, the light condensing characteristics of the light receiving sensor are reduced. This presents such a problem that the light receiving characteristics of the device cannot be sufficiently improved.

### SUMMARY OF THE INVENTION

It is an object of the present invention to provide a wafer-level chip scale package that contains a semiconductor element inside a hollow that is not easy to be filled with moisture.

In order to accomplish the above and other objects, a semiconductor device according to the present invention comprises: a semiconductor substrate; a semiconductor element provided in an element region on one principal surface of the semiconductor substrate; a sealing material provided on the one principal surface and enclosing the element region: and a light transmission material adhered to the semiconductor substrate via the sealing material, the light transmission material and the element region defining a hollow therebetween, the semiconductor device wherein: in the light transmission material, through holes penetrating through principal surfaces of the light transmission material are provided; and an inner side opening of each of the through holes is opened to the hollow and communicates therewith. The term through hole is intended to mean a structure that allows communication of the hollow of the semiconductor device to the outside atmosphere.

With this structure, since the hollow encapsulating the semiconductor element is connected to the outside atmosphere by the through holes provided in the light transmission material, the hollow has good permeability and thus moisture is not easily filled therein. This prevents degradation of the semiconductor element caused by moisture filled in the hollow and prevents mal-operation of the device caused by dew condensation on the inner surface of the hollow.

Further, with this structure, unlike conventional semiconductor devices in which the semiconductor substrate with the semiconductor element thereon is housed in a hollow container, because the hollow is provided only over the substrate, the device is significantly miniaturized.

The semiconductor device according to the present invention may be such that the semiconductor element is a light receiving sensor; between the sealing material enclosing the element region and the semiconductor element, a periphery region is provided facing the hollow provided thereabove; the inner side opening of each of the through holes in the light transmission material is opened facing the periphery region; and a passage of each of the through holes is extended to avoid facing an area above the element region.

That the inner side opening of each of the through holes is opened facing the periphery region and that the passage of each of the through holes does not face the hollow above the element region mean that the passage for the light injected into the light receiving sensor is not interfered with by the through holes. Thus, with this structure, since the light injected into the light receiving sensor is not scattered by the through holes, the light-receiving semiconductor device has high detecting accuracy.

Examples of the embodiment of the passage of each of the through holes not facing the area above the element region include, for example, a structure in which the passage of each of the through holes is extended in a perpendicular direction with respect to the periphery region, and a structure in which the passage of each of the through holes is extended in an outward direction away from immediately above the periphery region.

The semiconductor device according to the present invention may be such that the through holes provided in the light transmission material are composed of only through holes having respective inner openings opened facing the periphery region.

With this structure, since all the through holes are arranged in positions that do not cause interference of the passage for the light injected into the light receiving sensor, the light injected into the light receiving sensor is reliably prevented from being interfered with or scattered by the through holes. This further increases the detecting accuracy of the light-receiving semiconductor device.

The semiconductor device according to the present invention may further comprise: external output terminals each provided on the one principal surface and the other principal surface of the semiconductor substrate; and a through electrode penetrating through the principal surfaces of the semiconductor substrate and providing conduction between the semiconductor element and the external output terminals.

With this structure, since the semiconductor element is conducted to the external output terminals via the through electrode, there is no need for providing an extra space for use in extracting the element output out of the device. Thus, the semiconductor device is miniaturized enough to a wafer-level chip scale package.

The semiconductor device according to the present invention may comprise only one through hole provided in the light transmission material.

With this structure, since there is almost no decrease in the mechanical strength of the light transmission material, the light transmission material is hard to be broken. In addition, there is an increase in the long period usability of one semiconductor device. Further, since the arrangement pattern of the through hole acts as a sign by which the back and front, and left and right of the semiconductor device are easily recognized, there is such an advantage that the design arrangement pattern of the external output terminal provided on the rear surface of the device is recognizable without checking the rear surface of the device. This eliminates the need for checking at the time of mounting the device in electronic appliances, thus improving work efficiency associated with mounting of the device.

The semiconductor device according to the present invention may be such that two or more through holes are provided in the light transmission material, and the sizes of the two or more through holes are different from each other.

With this structure, since the permeability of the hollow further improves, the above-described degradation of the semiconductor chip and mal-operation of the device are further prevented. In addition, since the arrangement pattern of the differently sized through holes acts as a sign by which the back and front, and left and right of the semiconductor device are easily recognized, there is such an advantage that the design arrangement pattern of the external output terminal provided on the rear surface of the device is recognizable without checking the rear surface of the device. This eliminates the need for checking at the time of mounting the device in electronic appliances, thus improving work efficiency associated with mounting of the device. Although the permeability of the hollow improves as the number of the through holes increases, the through holes are preferably restricted to a number that does not cause the mechanical strength of the light transmission material to be undermined.

The semiconductor device according to the present invention may be such that the semiconductor element is a light receiving sensor; and the light transmission material is glass, and a surface thereof is coated with an infrared-ray cutting filter.

With this structure, injected light in which infrared rays are removed is detected by the light receiving sensor.

A method for producing a semiconductor device according to the present invention comprises: a semiconductor element forming step of forming a semiconductor element in an element region on one principal surface of a semiconductor wafer; a sealing material forming step of forming a sealing material on the one principal surface to enclose the element region; an adhering step of adhering a light transmission material having through holes penetrating through principal surfaces of the light transmission material to the semiconductor wafer via the sealing material, in such a manner that the light transmission material and the element region define a hollow therebetween and that an inner side opening of each of the through holes is opened to the hollow to communicate therewith; and after the adhering step, a thermal curing step of thermally curing the sealing material.

If, at the time of producing a semiconductor device, the hollow structure is formed in a sealed manner instead of allowing communication between the hollow and the outside atmosphere, there can be a time when the air inside the hollow is thermally expanded at the time of thermally curing the adhesive, which adheres the wafer to the light transmission material, and the pattern shape of the adhesive is deformed, resulting in a reduction in the design accuracy of the semiconductor device.

On the other hand, in the above-described method for producing a semiconductor device according to the present invention, since the inner side opening of each of the through holes is opened to the hollow and communicates therewith, the air thermally expanded at the time of the thermal curing step is released from the inside of the hollow to the outside thereof This inhibits the deformation of the pattern shape of the sealing material.

The method for producing a semiconductor device according to the present invention may further comprise, after the thermal curing step, a heat radiating step of causing the semiconductor wafer to radiate heat.

If, at the time of producing a semiconductor device, the hollow structure is formed in a sealed manner instead of allowing communication between the hollow and the outside atmosphere, the pressure inside the hollow becomes negative as it is gradually cooled by the heat radiation, which follows the thermal curing step. This causes external induction of water. As a result, moisture is filled in the hollow, which causes degradation of the semiconductor chip, and dew condensation occurs on the inner surface of the hollow, which causes mal-operation of the device. On the other hand, in the above-described method for producing a semiconductor device according to the present invention, since the hollow communicates with the outside thereof because of the through holes, the pressure inside the hollow is prevented from becoming negative at the time of the heat radiation step.

The method for producing a semiconductor device according to the present invention may be such that the semiconductor element is a light receiving sensor; the sealing material forming step comprises forming the sealing material in such a manner that the element region and a periphery region are enclosed, the periphery region being on the one principal surface of the semiconductor wafer in a periphery of the element region and not having the semiconductor element provided thereon; when adhering the light transmission material to the semiconductor wafer, the inner side opening of each of the through holes in the light transmission material is opened facing the periphery region; and a passage of each of the through holes is provided in the light transmission material to avoid facing the area above the element region.

With this structure, the through holes are arranged in positions that do not cause interference of the passage for the light injected into the light receiving sensor. This provides for a light-receiving semiconductor device with high detecting accuracy in which the light injected into the light receiving sensor is prevented from being interfered with or scattered by the through holes.

The method for producing a semiconductor device according to the present invention may be such that the semiconductor element is a light receiving sensor; the sealing material forming step comprises forming the sealing material in such a manner that the element region and a periphery region are enclosed, the periphery region being one principal surface of a periphery of the element region and not having the semiconductor element provided thereon; and when adhering the light transmission material to the semiconductor wafer, the inner side opening of each of the through holes in the light transmission material is opened facing only the periphery region, and a passage of each of the through holes is provided to avoid facing the area above the element region.

With this structure, all the through holes are arranged in positions that do not cause interference of the passage for the light injected into the light receiving sensor. This provides for a light-receiving semiconductor device with high detecting accuracy in which the light injected into the light receiving sensor is reliably prevented from being scattered by the through holes.

The method for producing a semiconductor device according to the present invention may further comprise: after the heat radiating step, a step of forming a front-surface protecting layer on the light transmission material to cover the inner side opening and an outer side opening of each of the through holes, the outer side opening being at the other end from the inner side opening; a step of processing the semiconductor wafer into a semiconductor substrate, the step comprising: supporting the light transmission material provided with the front-surface protecting layer thereon; and grinding one principal surface and the other principal surface of the semiconductor wafer; a step of forming an external output terminal in a surface of the semiconductor substrate to conduct the ground semiconductor element to the external output terminal; a dicing sheet applying step comprising, after removing the front-surface protecting layer to expose one principal surface of the light transmission material, applying a dicing sheet on the exposed one principal surface of the light transmission material to cover the outer side opening of each of the through holes, or instead of removing the front-surface protecting layer, applying the dicing sheet on the front-surface protecting layer; and after the dicing sheet applying step, a step of dicing the semiconductor substrate, the sealing material, and the light transmission material.

With this structure, since the grinding and dicing of the semiconductor wafer is carried out while covering the outer side opening of each of the through holes, ground fragments of the materials and water supplied at the time of grinding and dicing do not intrude into the hollow through the through holes. This reliably prevents damage to the semiconductor chip resulting from ground fragments and water, and occurrence of dew condensation on the inner surface of the hollow. According to the present invention described above, since the hollow of a semiconductor device in which a semiconductor element is encapsulated communicates with the outside atmosphere because of the through holes provided in the light transmission material, the hollow has good permeability and moisture is not filled in the hollow. This prevents degradation of the semiconductor chip and mal-operation of the device resulting from moisture. In addition, unlike conventional semiconductor devices in which the substrate is housed in the hollow container, by providing the hollow only over the substrate, the device is significantly miniaturized.

### BRIEF DESCRIPTION OF THE DRAWINGS

FIG. 1 is a plan view showing an example of a semiconductor device according to embodiment 1.

FIG. 2 is a cross section showing an example of the A-B line cross section shown in FIG. 1.

FIG. 3 is an enlarged view of a structure of the vicinity of a through electrode in the cross section of FIG. 2.

FIG. 4 is a view for describing a production process according to the method for producing a semiconductor device of embodiment 1, and is a schematic cross section of a semiconductor device in the course of production in which semiconductor elements and filled-in electrodes are provided on the wafer.

FIG. 5 is a view for describing a production process according to the method for producing a semiconductor device of embodiment 1, and is a schematic cross section of a semiconductor device in the course of production in which sealing materials are applied on the filled-in electrodes.

FIG. 6 is a view for describing a production process according to the method for producing a semiconductor device of embodiment 1, and is a schematic cross section of a semiconductor device in the course of production in which a light transmission material is provided on the sealing materials.

FIG. 7 is a view for describing a production process according to the method for producing a semiconductor device of embodiment 1, and is a schematic cross section of a semiconductor device in the course of production in which a front-surface protecting layer is provided on the light transmission material and the wafer is processed into a semiconductor substrate.

FIG. 8 is a view for describing a production process according to the method for producing a semiconductor device of embodiment 1, and is a schematic cross section of a semiconductor device in the course of production in which rear-surface wirings and rear-surface protecting films are provided on the rear surface of the semiconductor substrate.

FIG. 9 is a view for describing a production process according to the method for producing a semiconductor device of embodiment 1, and is a schematic cross section of a semiconductor device in the course of production in which soldering balls are provided on the rear-surface wirings.

FIG. 10 is a view for describing a production process according to the method for producing a semiconductor device of embodiment 1, and is a schematic cross section of a semiconductor device in the course of production immediately after the semiconductor device is diced into individual semiconductor devices.

FIG. 11 is a schematic cross section of a conventional CCD package.

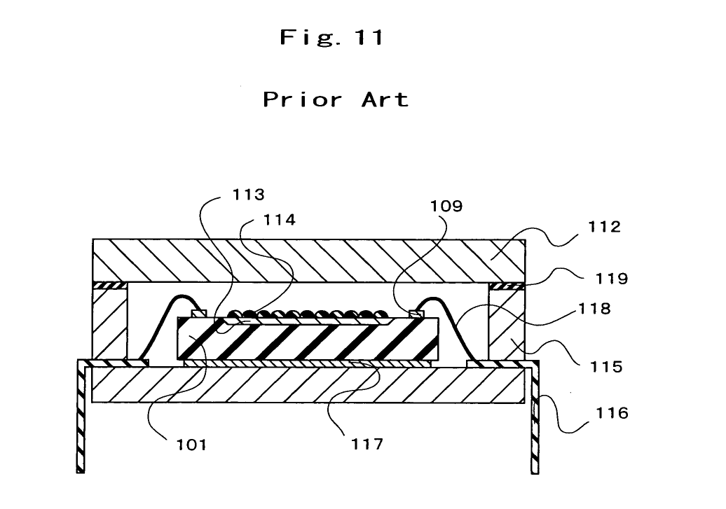

FIG. 12 is a schematic cross section of a conventional CCD module.

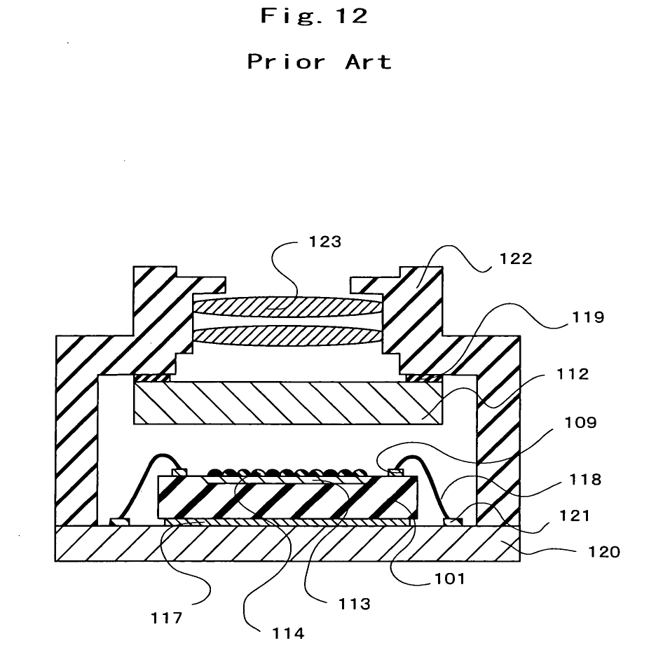

FIG. 13 is a plan view showing an example of a semiconductor device according to embodiment 2.

FIG. 14 is a plan view showing an example of a semiconductor device according to embodiment 3

FIG. 15 is a plan view showing an example of a semiconductor device according to embodiment 5.

FIG. 16 is a plan view showing an example of a semiconductor device according to an additional embodiment.

FIG. 17 is a cross section showing an example of the A-B line cross section shown in FIG. 16.

### DESCRIPTION OF REFERENCE NUMERAL IN THE DRAWINGS

1 Semiconductor substrate
2 Light transmission material
3 Through hole
4 Sealing material
5 Imaging element
6 Micro lens portion
7 Hollow
8 Through electrode
9 Rear-surface wiring
10 Rear-surface protecting film
11 Soldering ball
12 Through-hole insulating film
13 Electrode pad
14 Front-surface protecting film
15 Rear-surface insulating film
16 Wafer
17 Filled-in electrode
18 Front-surface protecting layer
19 Dicing sheet
20 Semiconductor device
21 Semiconductor electrode
22 Electrode region
23 Periphery region

### DESCRIPTION OF THE PREFERRED EMBODIMENTS

Preferred embodiments of the present invention will be described taking embodiment 1 below as an example.

### Embodiment 1

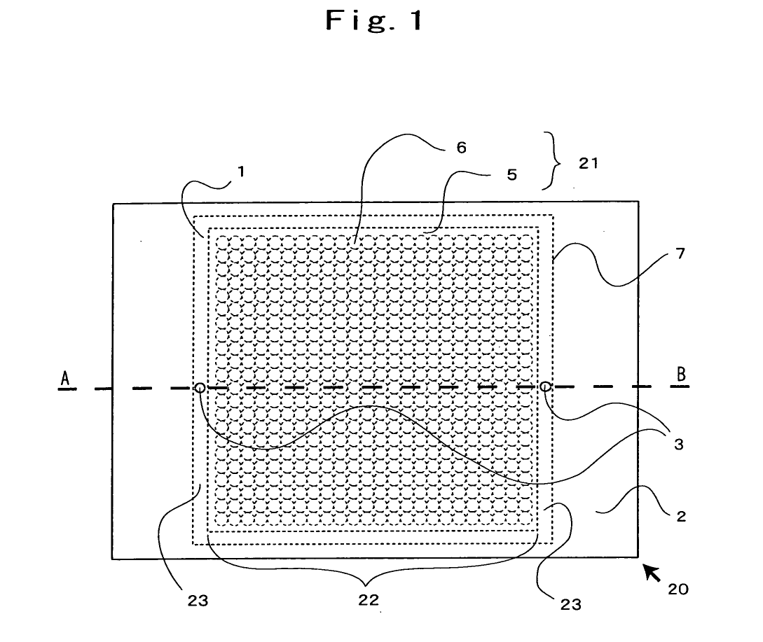

Semiconductor device 20 according to embodiment 1 has, as shown in the plan view of FIG. 1, light transmission material 2 of square-board external shape with a principal surface size of 5.0×4.2 mm and a thickness of 0.5 mm, and semiconductor substrate 1 of the same external shape as that of light transmission material 2 and of 0.1 mm thick. In addition, in element region 22 on one principal surface of semiconductor substrate 1, semiconductor element 21 with a region size of 3.5×3.3 mm is provided. Semiconductor element 21 is composed of imaging element 5 and micro lens portions 6. Element region 22 is not in contact with light transmission material 2 because of the intermediation of sealing material 4, described later. Hollow 7 (with a size of 4.0×3.8 mm and a height of 0.05 mm) is formed above element region 22 and periphery region 23. Periphery region 23 is provided externally along the periphery of the element region and on the one principal surface of semiconductor substrate 1 on which semiconductor element 21 is not provided.

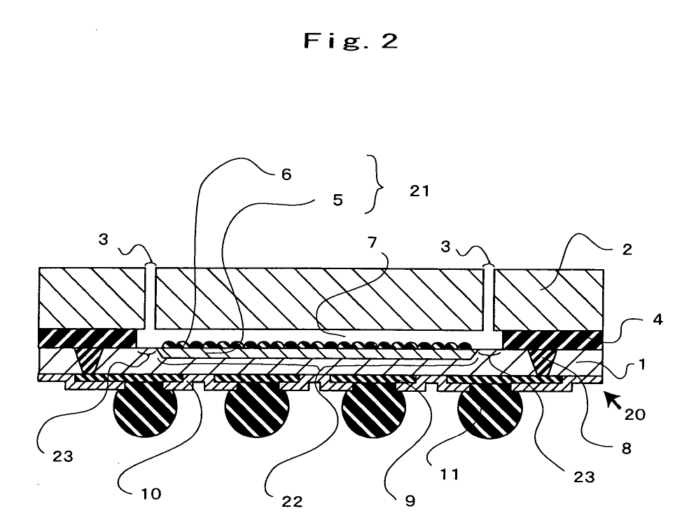

At two positions of light transmission material 2, through holes 3 (with an outer diameter of 0.2 mm) that penetrate through the principal surfaces of light transmission material 2 are provided. As shown in FIG. 2, which is a cross section showing the A-B line cross section shown in FIG. 1, the inner side opening of each of through holes 3 is opened above periphery region 23, by which hollow 7 is connected with the outside atmosphere. Through holes 3 are extended in a perpendicular direction with respect to the periphery region. For the purpose of enhancing the light receiving accuracy of the semiconductor device, described later, it is preferable to design the hole diameter of each of through holes 3 to be smaller than the width of periphery region 23. The cross sectional shape of each of through holes 3, on the other hand, is not limited to the circular shape as shown in FIG. 1; any shape can be used insofar as hollow 7 can communicate with the outside atmosphere.

Light transmission material 2 and semiconductor substrate 1 are fixed to each other via sealing material 4 of 0.05 mm thick. Also, in semiconductor substrate 1, through electrodes 8 are provided, and on the other principal surface of semiconductor substrate 1, which is the other side of the one principal surface, rear-surface wirings 9 are provided. By through electrodes 8, semiconductor element 21 is conducted to rear-surface wirings 9. In addition, to rear-surface wirings 9, soldering balls 11 that act as external output terminals are connected. The other portions of the rear-surface wirings than those portions connected with soldering balls 11 and portions of the other principal surface of the semiconductor substrate are covered with rear-surface protecting films 10.

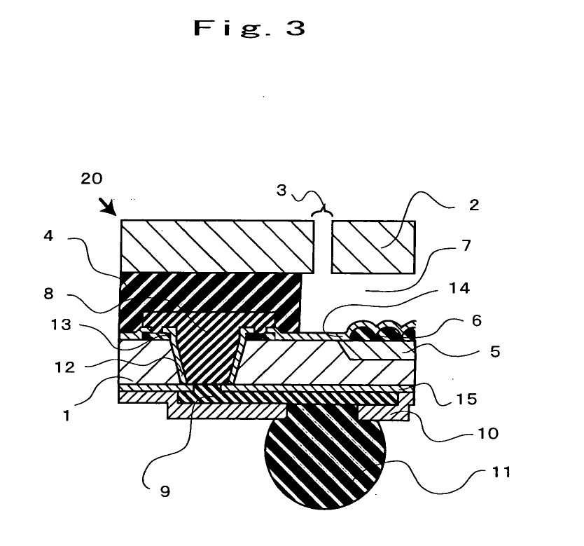

More specifically, as shown in FIG. 3, portions of the one principal surface of semiconductor substrate 1 and the surfaces of micro lens portions 6 are covered with front-surface protecting film 14, and portions of the other principal surface of semiconductor substrate 1 are covered with rear-surface insulating film 15. Also, between through electrode 8 and semiconductor substrate 1, through-hole insulating film 12 is provided. Because of the need for conduction between soldering ball 11 and semiconductor element 21, rear-surface insulating film 15 is not provided at the contact portion of through electrode 8 and rear-surface wiring 9, and front-surface protecting film 14 is not provided at the contact portion of electrode pad 13, which is provided on the one principal surface of semiconductor substrate 1 and conducted to semiconductor element 21, and through electrode 8.

In this semiconductor device 20, since hollow 7, which encapsulates semiconductor element 21, communicates with the outside atmosphere because of through holes 3, hollow 7 has good permeability and thus is not easily filled with moisture. This prevents degradation of semiconductor element 21 resulting from moisture filling the hollow and mal-operation of the device resulting from dew condensation on the inner surface of the hollow.

In addition, unlike conventional semiconductor devices in which the semiconductor substrate with the semiconductor element thereon is housed in the hollow container, because hollow 7 is provided over semiconductor substrate 1 with semiconductor element 21 provided thereon, the package size is miniaturized. Further, since semiconductor element 21 is conducted to soldering balls 11 via through electrodes 8, there is no need for providing an extra space for use in extracting the element output out of the device. Thus, the device can be miniaturized enough to a wafer-level chip scale package.

In addition, since the inner side opening of each of through holes 3 is opened facing periphery region 23, and through holes 3 are extended in a perpendicular direction with respect to periphery region 23, through holes 3 are arranged in positions that do not cause interference of the passage for the light injected into the light receiving sensor. Thus, the light externally injected through light transmission material 2 into semiconductor element 21 is not scattered by through holes 3. The semiconductor device therefore has high detecting accuracy.

It is noted that if light transmission material 2 is such that an infrared-ray cutting filter is coated on the glass lid, injected light in which infrared rays are removed is detected by the light receiving sensor.

The CSP (chip scale package) type CCD package according to embodiment 1 was prepared in the following manner.

First, in element region 22 on one principal surface of wafer 16, semiconductor element 21, acting as a light receiving sensor (CCD element) and composed of imaging element 5 and micro lens portions 6, was formed. Also formed in element region 22 was a periphery circuit (not shown) including electrode pad 13 conducted to semiconductor element 21. Micro lens portions 6, portions of electrode pad 13, and the one principal surface of wafer 16 were covered with front-surface protecting film 14 made of SiO₂, Si₃N₄, or the like.

Next, a resist was applied on the one principal surface of wafer 16, and by exposure and development, a window was provided above electrode pad 13. Next, the window portion of the resist was etched by dry etching to remove the portion of the pad at the window portion, the insulating film under the pad portion, and the Si of wafer 16, thus forming a hole portion. The resist was then removed.

Subsequently, an inorganic film of SiO₂, Si₃N₄, or the like was formed along the wall surface of the hole portion by, for example, the CVD method, thus forming through-hole insulating film 12. Next, by the sputtering method using Ti and Cu, on the one principal surface of wafer 16 including the inner wall and bottom of the hole portion, a metal layer acting both as a plating seed layer and a barrier metal layer was formed.

After forming the metal layer, a resist was applied, and by exposure and development, a resist window portion was formed by providing a window at the position where the hole portion and electrode pad 13 were formed, that is, the position where filled-in electrode 17 was to be formed.

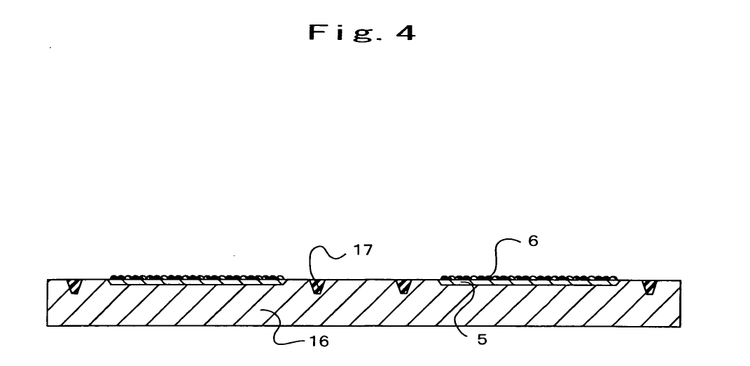

Next, by Cu electroplating, Cu was deposited on the resist window portion and the metal layer on the inside of the hole portion, thus forming filled-in electrode 17. Lastly, the resist and unnecessary metal layer were removed, thus preparing wafer 16 as shown in FIG. 4.

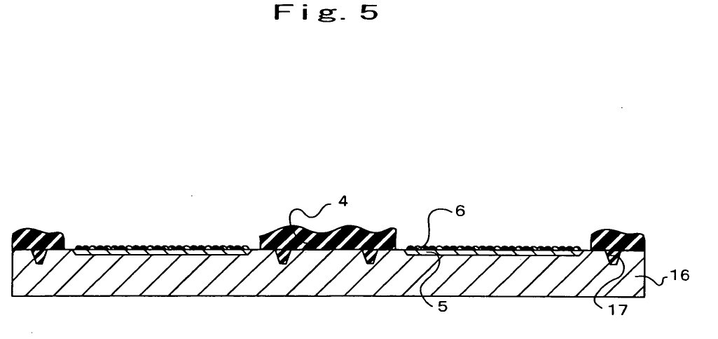

Subsequently, as shown in FIG. 5, to cover filled-in electrode 17 and its periphery on the one principal surface of wafer 16, a paste resin mainly made of epoxy resin was transferred by printing. Thus, sealing material 4 was formed on wafer 16 to enclose, as well as element region 22 which was on the one principal surface on which semiconductor element 21 was provided, periphery region 23 which was the periphery of element region 22 and was on the one principal surface on which semiconductor element 21 was not provided.

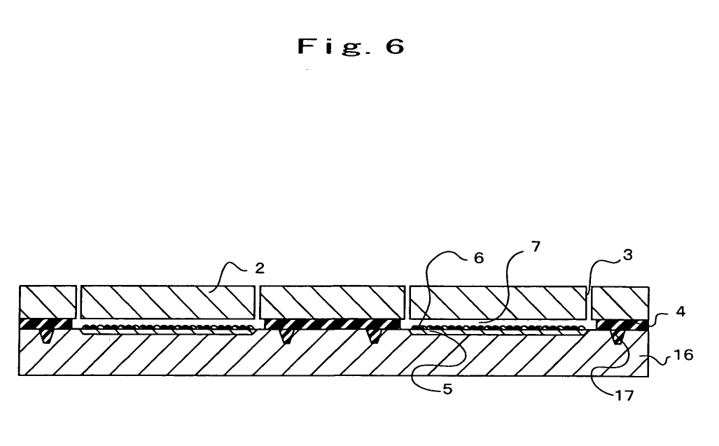

Next, light transmission material 2 made of glass was mounted on wafer 16 via sealing material 4. Light transmission material 2 had through holes 3 penetrating through the both principal surfaces of light transmission material 2. Next, by heating, the resin component of sealing material 4 was finally cured. Light transmission material 2 used here had the same principal surface size as that of wafer 16. In addition, as shown in FIG. 6, through holes 3 in light transmission material 2 were provided in such a manner that when light transmission material 2 was adhered to wafer 16, the inner side opening of each of through holes 3 was opened facing only periphery region 23, and that the passage of each of through holes 3 was extended to avoid facing the area above element region 22. By adhering light transmission material 2 to wafer 16, hollow 7 was formed between element region 22 and light transmission material 2.

Next, wafer 16 was left for a while to allow sealing material 4 to radiate heat.

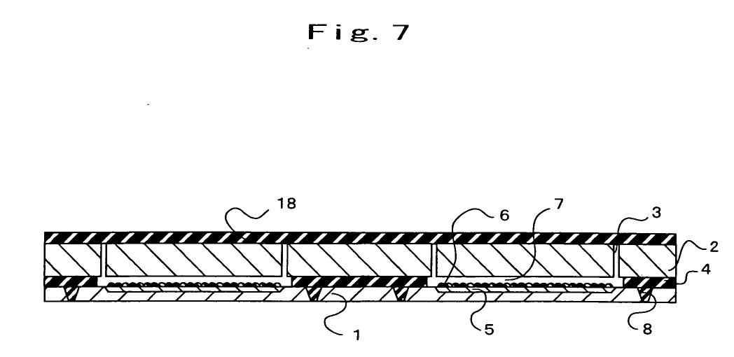

Subsequently, to cover the inner side opening and outer side opening, which was at the other end from the inner side opening, of each of through holes 3, front-surface protecting layer 18 made of a material detachable by ultraviolet rays was provided on light transmission material 2. Then, by using a conventional rear-surface polishing method, the one principal surface and the other principal surface, that is, the rear-surface of wafer 16 were polished until the tip of filled-in electrode 17 was exposed, and thus, as shown in FIG. 7, wafer 16 was processed into semiconductor substrate 1 and filled-in electrode 17 was processed into through electrode 8. It is noted that front-surface protecting layer 18 can be provided by applying a sheet-formed protecting film or by applying a liquid resin. It is also noted that the polished surface that has been subject to rear-surface polishing can be subject to mirror surface treatment (washing) by using the chemical mechanical polishing (CMP) methods or the etching methods such as dry etching and wet etching.

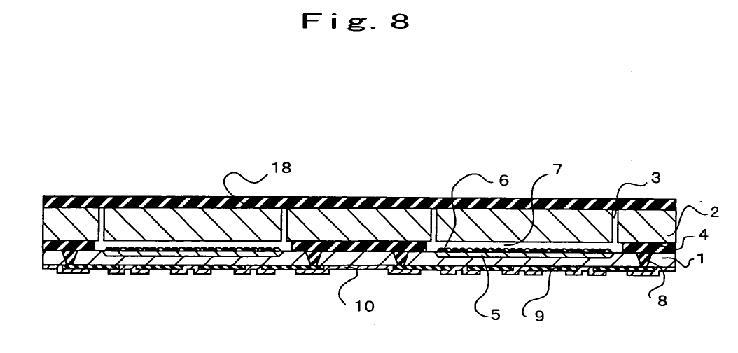

Next, as shown in FIG. 8, on the rear surface of semiconductor substrate 1, rear-surface insulating film 15 (see FIG. 3), rear-surface wirings 9 conducted to through electrode 8, and rear-surface protecting film 10 were formed.

Rear-surface insulating film 15 and rear-surface protecting film 10 can be formed in such a manner that a photosensitive organic film material mainly made of epoxy or polybenzoxazole is applied, and after providing windows at the portions required for connections between the electrodes by exposure and development, the material is cured by thermal treatment, or that after providing an inorganic film made of SiO₂, Si₃N₄, or the like, windows are provided by etching using a photo resist mask.

Also, rear-surface wirings 9 can be formed in such a manner that after providing a titanium (Ti) layer, acting both as a plating seed layer and a barrier metal layer, and a copper (Cu) layer by the sputtering method, windows for copper plating are provided by etching using a photo resist mask, and the windowed portions are subject to plating growth of copper wirings by electroplating, or that after providing a metal layer made of copper (Cu), nickel copper (CuNi), titanium (Ti), or the like by the sputtering method, etching is carried out using a photo resist mask.

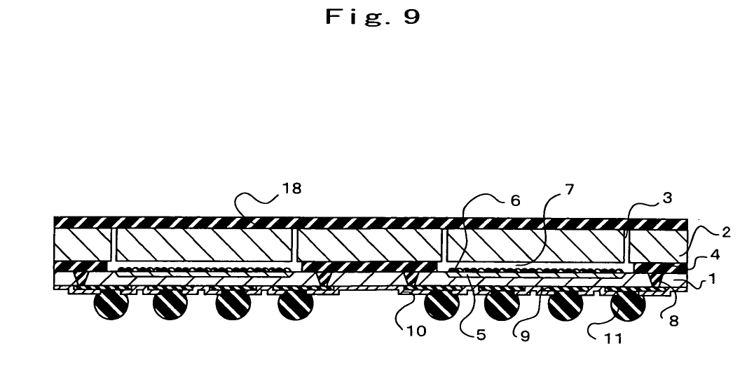

Next, after applying a rosin-based flux on the windowed portions of rear-surface protecting film 10, as shown in FIG. 9, soldering balls 11 made of tin (Sn), silver (Ag), and copper (Cu) were provided on the windowed portions by thermal treatment. The flux was washed away after provision of soldering balls 11.

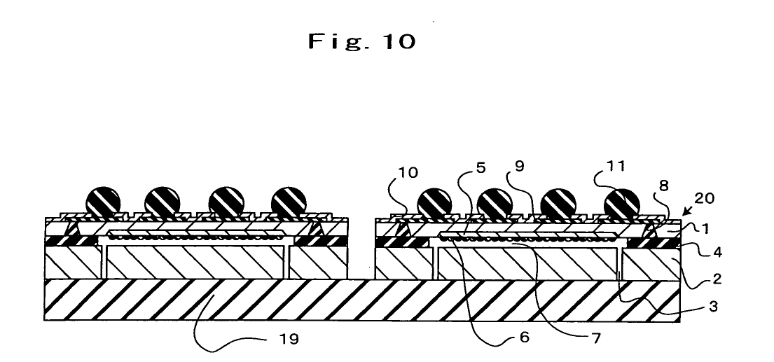

Lastly, by radiation of ultraviolet rays, front-surface protecting layer 18 was detached from light transmission material 2, and to replace the layer, dicing sheet 19 was applied on light transmission material 2. Then, by using a dicing apparatus, individual semiconductor devices 20 were cut apart from each other, as shown in FIG. 10. At the time of the dicing, the substrate can be supported in such a state that instead of removing front-surface protecting layer 18, dicing sheet 19 is applied on the layer. Also, while front-surface protecting layer 18 can be detached by using some agent, it is preferable to use detachment methods involving ultraviolet rays, for the purpose of reliably preventing water from intruding into hollow 7 through through holes 3.

In the method for producing a semiconductor device according to embodiment 1, by adhering light transmission material 2, in which through holes 3 are provided, to wafer 16 via sealing material 4 in such a manner that the inner side opening of each of through holes 3 is opened to hollow 7 to communicate therewith, the air thermally expanded at the time of thermal curing of sealing material 4 is exhausted from the inside of hollow 7 to the outside thereof This significantly prevents deformation of the pattern shape of sealing material 4 at the time of thermal curing, thus improving the design accuracy of the semiconductor device.

Further, if the hollow is formed in a sealed manner instead of allowing communication between hollow 7 and the outside atmosphere, the pressure inside hollow 7 becomes negative as it is gradually cooled by the heat radiation, which follows the thermal curing of the adhesive. This causes external induction of water. As a result, moisture is filled in the hollow, which causes degradation of the semiconductor chip, and dew condensation occurs on the inner surface of the hollow, which causes mal-operation of the device. On the other hand, in the method for producing a semiconductor device according embodiment 1, since hollow 7 communicates with the outside atmosphere because of through holes 3, the pressure inside the hollow is prevented from becoming negative in the course of allowing sealing material 4 to radiate heat.

In addition, since the rear-surface polishing and dicing are carried out while covering the other side opening of each of through holes 3, ground fragments of the constituent materials and water supplied at the time of rear-surface polishing and dicing do not intrude into hollow 7 through through holes 3. This reliably prevents damage to the semiconductor chip resulting from ground fragments and water, and occurrence of dew condensation on the inner surface of the hollow, which causes mal-operation of the device.

It is noted that in terms of allowing communication between the hollow and the outside atmosphere, through holes 3 can be provided in sealing material 4 instead of light transmission material 2, but preferably in light transmission material 2, as in embodiment 1. This is because what is important is to secure communication between the hollow and the outside atmosphere at the time of the thermal curing and heat radiation of the sealing material, and thus the through holes need to be provided in the sealing material prior to thermal curing. In this case, however, by the thermal curing, the through holes can be welded and closed, making it hard to secure sufficient permeation. Further, in the dicing step, such an inconvenience occurs that via the portions on which the adhesive is not applied, water and Si segments intrude into the hollow portion.

By penetrating through the sealing material and filling therein a hollow pipe, stable permeation is secured at the time of thermal curing. But this is not preferred because of an increase in the number of parts for the device and working process steps.

As has been described hereinbefore, in embodiment 1, since moisture is not easily filled in the hollow, degradation of the semiconductor element and mal-operation of the device resulting from dew condensation on the inner surface of the hollow are prevented. Further, the semiconductor device is miniaturized enough to a wafer-level chip scale package. In addition, the light injected into the semiconductor element is not scattered by the through holes. The semiconductor device therefore has high detecting accuracy.

Further, in embodiment 1, the deformation of the pattern shape of the sealing material caused by thermal curing is significantly prevented. In addition, damage to the semiconductor chip resulting from ground fragments and water involved in rear-surface polishing and dicing, and mal-operation of the device resulting from dew condensation on the inner surface of the hollow are reliably prevented.

### Embodiment 2

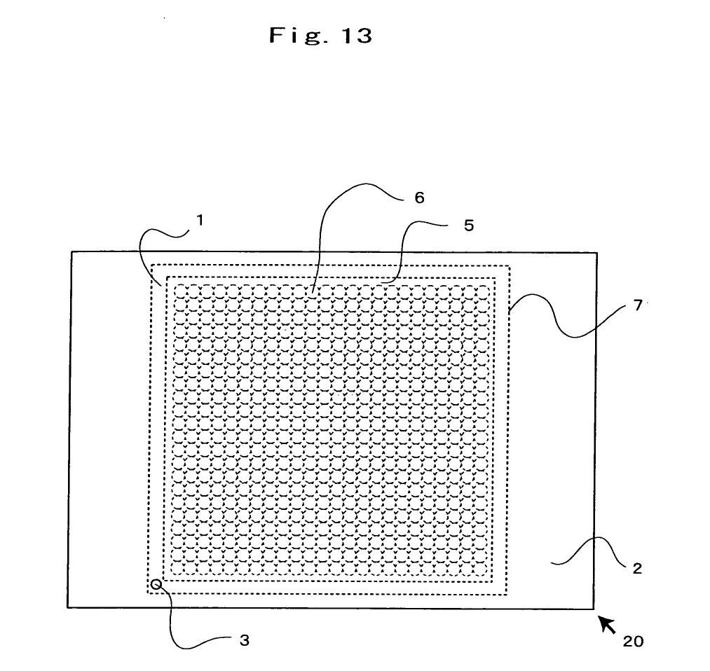

The semiconductor device according to embodiment 2 is, as shown in FIG. 13, similar to the semiconductor device in embodiment 1 except that only one through hole 3 is provided in light transmission material 2. The light transmission material, while having a through hole, has even higher mechanical strength and thus is not easily broken. Thus, the effect of improving the long time reliability of the semiconductor device is provided, as well as providing the same advantageous effects as in embodiment 1.

In addition, since through hole 3 can act as a sign by which the back and front, and left and right of the semiconductor device are easily recognized, the design arrangement pattern of soldering balls 11 provided on the rear surface of the device is recognizable without checking the rear surface of the device. This eliminates the need for checking at the time of mounting the device in electronic appliances, thus improving work efficiency associated with mounting of the device.

### Embodiment 3

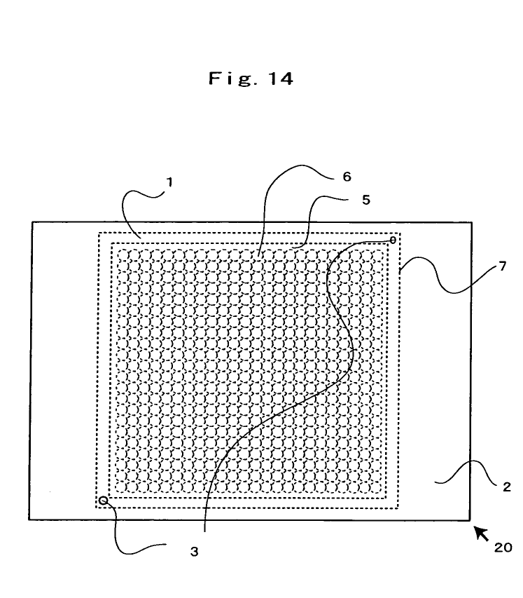

The semiconductor device according to embodiment 3 is, as shown in FIG. 14, similar to the semiconductor device in embodiment 1 except that two differently sized through holes 3 are provided in light transmission material 2. Since the arrangement pattern of the differently sized through holes can act as a sign by which the back and front, and left and right of the semiconductor device are easily recognized, there is such an effect, as well as the same advantageous effects as in embodiment 1, that the design arrangement pattern of soldering balls 11 provided on the rear surface of the device is recognizable without checking the rear surface of the device.

As described above, it is preferable to design the diameter of cross-sectional shape of each of through holes 3 to be smaller than the width of periphery region 23. The cross sectional shape of each of through holes 3 is not limited to a particular shape.

### Embodiment 4

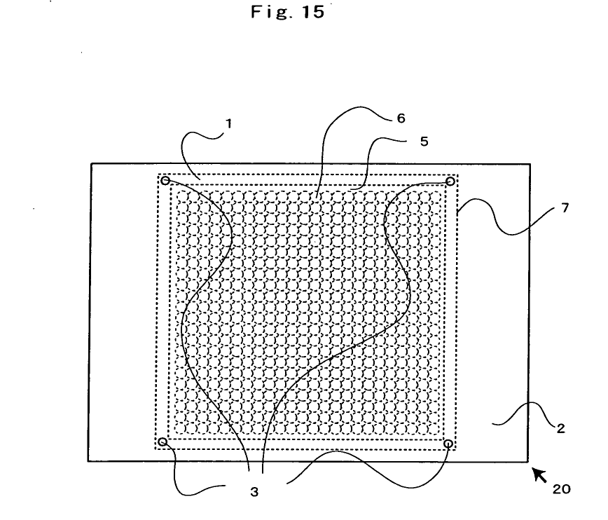

The semiconductor device according to embodiment 4 is, as shown in FIG. 15, similar to the semiconductor device in embodiment 1 except that four through holes 3 are provided in light transmission material 2. Since the permeability of the hollow further improves, there is such an effect, as well as the same advantageous effects as in embodiment 1, that further prevents degradation of the semiconductor device and mal-operation of the device resulting from moisture.

Although the permeability of the hollow improves as the number of the through holes, provided in the light transmission material, increases, too many through holes cause the light transmission material to be easily broken. Thus, the through holes are preferably restricted to a number that does not cause the mechanical strength of the light transmission material to be undermined.

### Supplementary Remarks

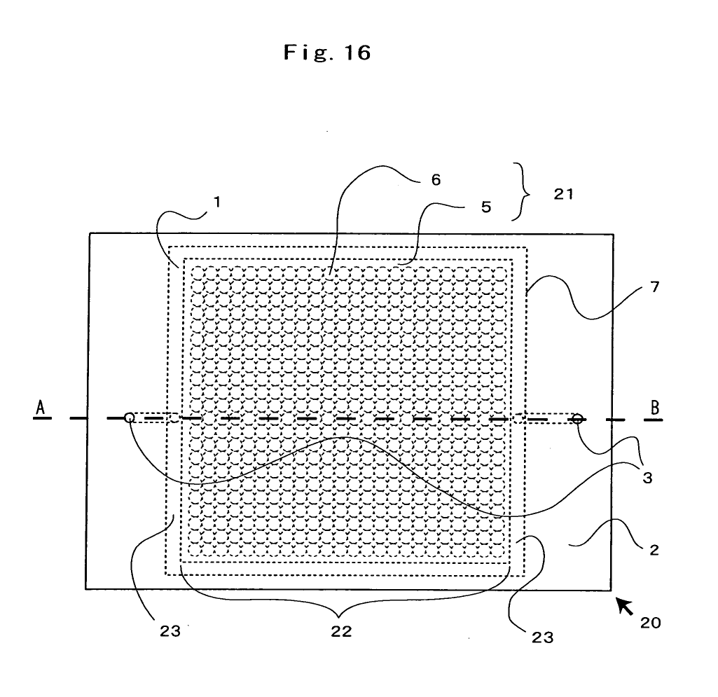

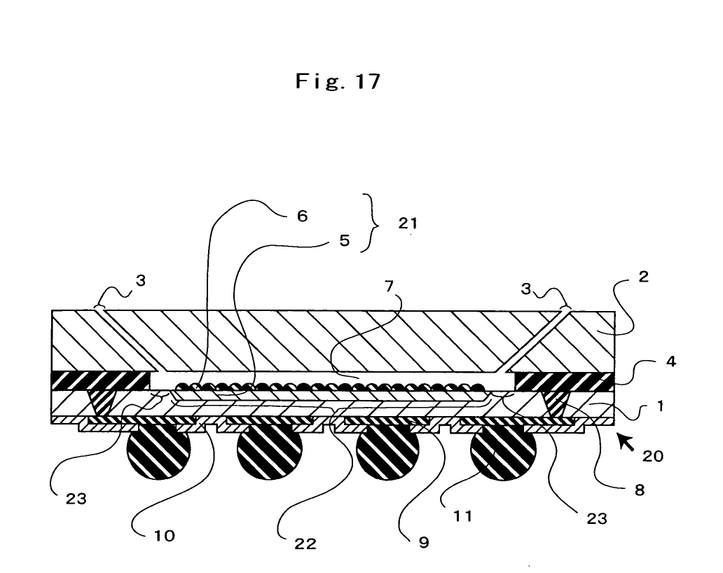

(1) In embodiments 1 to 4, such a structure has been described that the passage of through hole 3 is extended in a perpendicular direction with respect to periphery region 23. Since what is important in terms of improving the light receiving accuracy of the semiconductor device is that the through hole is provided in a position that does not cause interference of the passage for the light injected into the semiconductor element, such a structure can be contemplated that the passage of through hole 3 is extended in an outward direction away from element region 22 starting from the inner side opening, as shown in FIGS. 16 and 17.

(2) While in embodiments 1 to 4 the through hole has been described to have a hole structure, the through hole is not to be restricted to the hole structure insofar as hollow 7 can communicate with the outside atmosphere. For example, such a structure can be contemplated that the permeability of the through hole is made higher than that of the light transmission material, including providing a material with a high efficiency of air permeation at the portion of the through hole.

(3) While in embodiments 1 to 4 such a structure has been described that the through hole provided in light transmission material 2 is close to the sealing material, this structure is not to be restrictive insofar as the inner side opening of the through hole is opened facing periphery region 23, which is provided externally along the periphery of the element region and on the one principal surface on which semiconductor element 21 is not provided, and the passage of the through hole is extended to avoid facing the area above the element region. For example, such a structure can be contemplated that a plurality of element regions 22 are provided in an insular and separate manner, and the inner side opening of a through hole is opened facing the periphery region between adjacent element regions.

(4) While in embodiments 1 to 4 such a case has been described that the inner side opening of through hole 3, provided in light transmission material 2, is opened facing only periphery region 23, this is not to exclude the device structure that contains a through hole that is opened to the hollow to face element region 22. However, to reliably prevent injected light from being scattered by the through hole, such a structure is preferable that all the inner side openings of the through holes are opened facing periphery region 23, as described in embodiments 1 to 4.

(5) While in embodiments 1 to 4, sealing material 4 is formed by transferring a paste resin by printing, sealing material 4 can be formed by exposure and development after applying a photosensitive resin made of epoxy, polyimide, acryl, or the like. Also, sealing material 4 can be formed by applying a sheet-formed adhesive resin made of epoxy, polyimide, or the like with the portion thereof corresponding to the hollow being hollowed out.

As has been described hereinbefore, according to the present invention, since the semiconductor element is encapsulated in a hollow structure that is not easily filled with moisture, the present invention can be used to prevent degradation of semiconductor elements and mal-operation of devices. Therefore, industrial applicability of the present invention is considerable.

What is claimed is:

1. A semiconductor device comprising:
a semiconductor substrate;
a semiconductor element provided in an element region on one principal surface of the semiconductor substrate;
a sealing material provided on the one principal surface and enclosing the element region: and
a light transmission material adhered to the semiconductor substrate via the sealing material, the light transmission material and the element region defining a hollow therebetween, the semiconductor device wherein:
in the light transmission material, through holes penetrating through principal surfaces of the light transmission material are provided; and
an inner side opening of each of the through holes is communicates with the hollow.

2. The semiconductor device according to claim 1, wherein:
the semiconductor element is a light receiving sensor;
between the sealing material enclosing the element region and the semiconductor element, a periphery region is provided facing the hollow provided thereabove;
an inner side opening of each of the through holes in the light transmission material is opened facing the periphery region; and
a passage of each of the through holes is extended to avoid facing an area above the element region.

3. The semiconductor device according to claim 1, further comprising:
external output terminals each provided on the one principal surface and the other principal surface of the semiconductor substrate; and
a through electrode penetrating through the principal surfaces of the semiconductor substrate and providing conduction between the semiconductor element and the external output terminals.

4. The semiconductor device according to claim 1, comprising only one through hole provided in the light transmission material.

5. The semiconductor device according to claim 1, comprising two or more through holes provided in the light transmission material, sizes of the two or more through holes being different from each other.

6. The semiconductor device according to claim 1, wherein:
the semiconductor element is a light receiving sensor; and
the light transmission material is glass, a surface thereof being coated with an infrared-ray cutting filter.

7. The semiconductor device according to claim 2, wherein the passage of each of the through holes is extended in a perpendicular direction with respect to the periphery region.

8. The semiconductor device according to claim 2, wherein the passage of each of the through holes is extended in an outward direction away from immediately above the periphery region.

9. The semiconductor device according to claim 2, wherein the through holes provided in the light transmission material are composed of only through holes having respective inner openings opened facing the periphery portion.

10. A method for producing a semiconductor device, the method comprising:
a semiconductor element forming step of forming a semiconductor element in an element region on one principal surface of a semiconductor wafer;
a sealing material forming step of forming a sealing material on the one principal surface to enclose the element region;
an adhering step of adhering a light transmission material having through holes penetrating through principal surfaces of the light transmission material to the semiconductor wafer via the sealing material, in such a manner that the light transmission material and the element region define a hollow therebetween and that an inner side opening of each of the through holes is opened to the hollow to communicate therewith; and
after the adhering step, a thermal curing step of thermally curing the sealing material.

11. The method for producing a semiconductor device according to claim 10, further comprising, after the thermal curing step, a heat radiating step of causing the semiconductor wafer to radiate heat.

12. The method for producing a semiconductor device according to claim 11, wherein:
the semiconductor element is a light receiving sensor;
the sealing material forming step comprises forming the sealing material in such a manner that the element region and a periphery region are enclosed, the periphery region being on the one principal surface of the semiconductor wafer in a periphery of the element region and not having the semiconductor element provided thereon;
when adhering the light transmission material to the semiconductor wafer, the inner side opening of each of the through holes in the light transmission material is opened facing the periphery region; and
a passage of each of the through holes is provided in the light transmission material to avoid facing an area above the element region.

13. The method for producing a semiconductor device according to claim 12, wherein when adhering the light transmission material to the semiconductor wafer, the inner side opening of each of the through holes in the light transmission material is opened facing only the periphery region.

14. The method for producing a semiconductor device according to claim 13, further comprising:
after the heat radiating step, a step of forming a front-surface protecting layer on the light transmission material to cover the inner side opening and an outer side opening of each of the through holes, the outer side opening being at the other end from the inner side opening;
a step of processing the semiconductor wafer into a semiconductor substrate, the step comprising: supporting the light transmission material provided with the front-surface protecting layer thereon; and grinding one principal surface and the other principal surface of the semiconductor wafer;
a step of forming an external output terminal in a surface of the semiconductor substrate to conduct the ground semiconductor element to the external output terminal;
a dicing sheet applying step comprising, after removing the front-surface protecting layer to expose one principal surface of the light transmission material, applying a dicing sheet on the exposed one principal surface of the light transmission material to cover the outer side opening of each of the through holes, or instead of removing the front-surface protecting layer, applying the dicing sheet on the front-surface protecting layer; and
after the dicing sheet applying step, a step of dicing the semiconductor substrate, the sealing material, and the light transmission material.

15. The method for producing a semiconductor device according to claim 10, wherein:
the semiconductor element is a light receiving sensor;
the sealing material forming step comprises forming the sealing material in such a manner that the element region and a periphery region are enclosed, the periphery region being on the one principal surface of the semiconductor wafer in a periphery of the element region and not having the semiconductor element provided thereon;
when adhering the light transmission material to the semiconductor wafer, the inner side opening of each of the through holes in the light transmission material is opened facing the periphery region; and
a passage of each of the through holes is provided in the light transmission material to avoid facing an area above the element region.

16. The method for producing a semiconductor device according to claim 15, wherein when adhering the light transmission material to the semiconductor wafer, the inner side opening of each of the through holes in the light transmission material is opened facing only the periphery region.

17. The method for producing a semiconductor device according to claim 16, further comprising:
after the heat radiating step, a step of forming a front-surface protecting layer on the light transmission material to cover the inner side opening and an outer side opening of each of the through holes, the outer side opening being at the other end from the inner side opening;
a step of processing the semiconductor wafer into a semiconductor substrate, the step comprising: supporting the light transmission material provided with the front-surface protecting layer thereon; and grinding one principal surface and the other principal surface of the semiconductor wafer;
a step of forming an external output terminal in a surface of the semiconductor substrate to conduct the ground semiconductor element to the external output terminal;
a dicing sheet applying step comprising, after removing the front-surface protecting layer to expose one principal surface of the light transmission material, applying a dicing sheet on the exposed one principal surface of the light transmission material to cover the outer side opening of each of the through holes, or instead of removing the front-surface protecting layer, applying the dicing sheet on the front-surface protecting layer; and
after the dicing sheet applying step, a step of dicing the semiconductor substrate, the sealing material, and the light transmission material.

18. The method for producing a semiconductor device according to claim 10, wherein when adhering the light transmission material to the semiconductor wafer, the inner side opening of each of the through holes in the light transmission material is opened facing only the periphery region.

19. The method for producing a semiconductor device according to claim 18, further comprising:
after the heat radiating step, a step of forming a front-surface protecting layer on the light transmission material to cover the inner side opening and an outer side opening of each of the through holes, the outer side opening being at the other end from the inner side opening;
a step of processing the semiconductor wafer into a semiconductor substrate, the step comprising: supporting the light transmission material provided with the front-surface protecting layer thereon; and grinding one principal surface and the other principal surface of the semiconductor wafer;
a step of forming an external output terminal in a surface of the semiconductor substrate to conduct the ground semiconductor element to the external output terminal;
a dicing sheet applying step comprising, after removing the front-surface protecting layer to expose one principal surface of the light transmission material, applying a dicing sheet on the exposed one principal surface of the light transmission material to cover the outer side opening of each of the through holes, or instead of removing the front-surface protecting layer, applying the dicing sheet on the front-surface protecting layer; and
after the dicing sheet applying step, a step of dicing the semiconductor substrate, the sealing material, and the light transmission material.
